(19) United States
(12) Patent Application Publication
(10) Pub. No.: US 2012/0075125 A1
(43) Pub. Date: Mar. 29, 2012

(54) HANDGRIP KEYBOARD

(75) Inventors: KUNIHIKO MIWA, KANAGAWA-KEN (JP); AKIHIKO MIZUTANI, KANAGAWA-KEN (JP); RYOHTA NOMURA, KANAGAWA-KEN (JP)

(73) Assignee: LENOVO (SINGAPORE) PTE. LTD., Singapore (SG)

(21) Appl. No.: 12/891,064

(22) Filed: Sep. 27, 2010

(51) Int. Cl. H03K 17/94

(52) U.S. Cl. 341/22

(57) ABSTRACT

A keyboard includes first and second keyboard units. The first and second keyboard units comprise a first housing and a second housing, respectively. The first housing and the second housing are adapted to be attached and detached from an electronic device. A set of input keys may be disposed on at least one of the first and second housings.

### BACKGROUND OF THE INVENTION

The present invention relates generally to keyboards and, more specifically, to handgrip keyboards for a communication device, such as a slate personal computer (PC).

In recent years, portable computers have evolved from transportable suitcase style computers, to laptops or notebooks, and then to slate PCs (also referred to as “tablets” or “pure tablets”). Portable laptops or notebook computers generally have full-sized or nearly full-sized keyboards that allow data entry. However, such computers do not readily allow data entry when the user is standing, in motion, or away from a table.

Slate PCs may allow a user enter data while standing, in motion, or away from a table by using a stylus or touch screen. Stylus or touch screen data entry is much slower than data entry by using a full sized keyboard, particularly if the user is experienced with a keyboard.

Therefore, it can be seen that there is a need for a slate PC to have a keyboard for rapid data entry.

### SUMMARY

In one aspect, a keyboard system comprises the first and second keyboard units having a first housing and a second housing, respectively, wherein the first housing and the second housing are adapted to be attached and detached from an electronic device; and a set of input keys disposed on at least one of the first and second housings.

In another aspect, an electronic computing device comprises a housing having a front face and an opposing rear face; a processor within the housing; a screen attached to the housing at the front face in which the screen is coupled to be operable by the processor to display data to a user of the device; and first and second foldable keyboard units comprising input keys, the first and second foldable keyboard units are adapted to be detachably affixed to an edge of the housing.

In a further aspect, a foldable keyboard comprises a lower housing; and an upper housing operably coupled to the lower housing for movement between an open mode and a folded mode, wherein, in the open mode, the foldable keyboard is detachable from a slate PC; and wherein, in the folded mode, the foldable keyboard is adapted to affix to an edge of the slate PC in a position permitting blind data entry via keys in at least one of the lower housing and the upper housing

These and other features, aspects and advantages of the present invention will become better understood with reference to the following drawings, description and claims.

### BRIEF DESCRIPTION OF THE DRAWINGS

FIG. 1 is a perspective view of an exemplary embodiment;

FIG. 2A is a front view of a first keyboard unit in an open mode, according to an exemplary embodiment;

FIG. 2B is a perspective view of the first keyboard unit of FIG. 2A in a folded mode;

FIG. 2C is a front view of a second keyboard unit in an open mode according to an exemplary embodiment;

FIG. 2D is a perspective view of the second keyboard unit of FIG. 2C in a folded mode;

FIG. 3A is a front view of a first keyboard unit in an open mode according to another exemplary embodiment;

FIG. 3B is a perspective view of the first keyboard unit of FIG. 3A in a folded mode; and

FIGS. 4A-4D show the steps of using the exemplary embodiments shown in FIGS. 2A through 2D.

### DETAILED DESCRIPTION OF EMBODIMENTS

The following detailed description is of the best currently contemplated modes of carrying out exemplary embodiments. The description is not to be taken in a limiting sense, but is made merely for the purpose of illustrating the general principles, since the scope of the embodiments is best defined by the appended claims.

Various inventive features are described below that can each be used independently of one another or in combination with other features.

Broadly, exemplary embodiments comprise a keyboard system having a first keyboard unit and a second keyboard unit which, together, may provide a full alphabetic array of letters (A-Z) and numbers 0-9. More specifically, exemplary embodiments of a keyboard system provide a total of 26 alphabetic keys with additional keys being utilized for numbers, symbols, or functions. According to exemplary embodiments, each keyboard unit may comprise an upper housing and a lower housing. A folding linkage may be used to connect the upper housing and the lower housing. The folding linkage may provide a mechanism for the upper housing to pivot between an open mode (with the upper housing being aligned in a substantially level plane relative to the lower housing with input keys disposed on both the upper and lower housings, facing upward) and a folded mode (with the upper housing being disposed at an angled position with respect to the lower housing). In the folded mode, the keyboard units may be detachably affixed to edges of a slate PC to provide keyboard data entry.

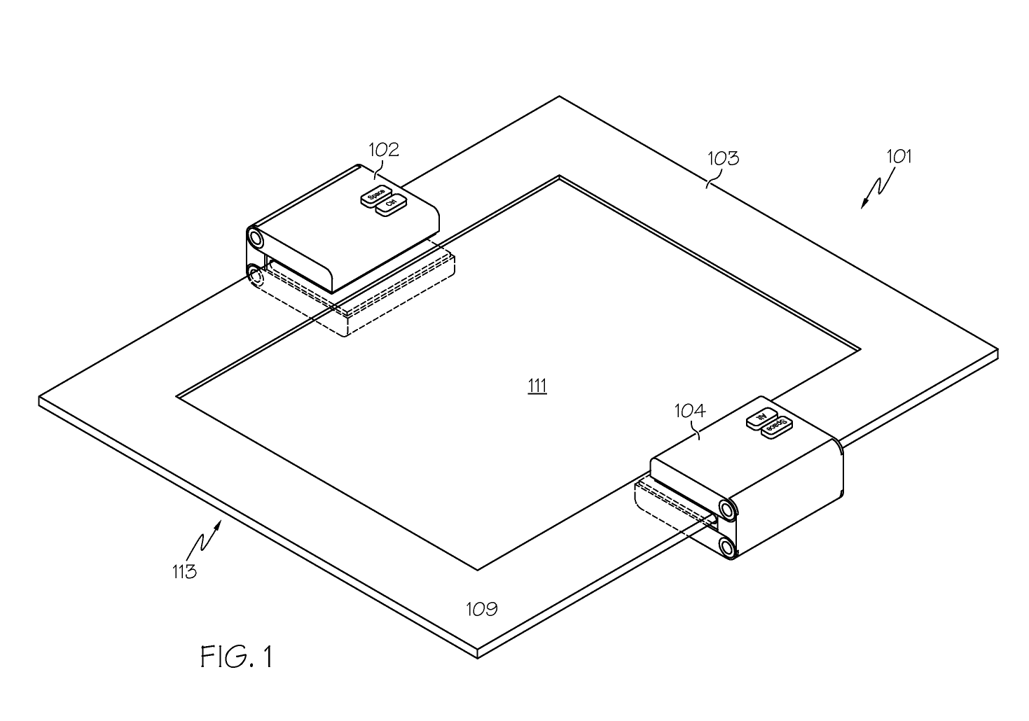

Referring to FIG. 1, a keyboard system may include a first keyboard unit 102 and a second keyboard unit 104. The first keyboard unit 102 and the second keyboard unit 104 may be attachable to and detachable from a slate PC 101.

The slate PC 101 may include a housing 103 and a processor (not shown) within the housing 103. The housing 103 may comprise a front face 109 and an opposite rear face 113. A screen 111 may be affixed to the housing 103 at the front face 109 in which the screen 111 may be coupled to be operable by the processor to display data to a user of the slate PC 101.

The first and second keyboard units 102 and 104 may be connected to the slate PC 101 via a cable (not shown), such as a universal serial bus (USB) cable, for example. Alternatively, the keyboard units 102 and 104 may communicate with the slate PC 101 via a wireless connection. Wireless keyboards may use an optical signal such as infrared (IR) connection or a radio (RF) connection such as, a Bluetooth™, wireless-USB, for example. Bluetooth™ uses radio frequencies to provide wireless data transfer between Bluetooth™ enabled devices. Bluetooth™ is a fairly ubiquitous wireless data transfer technology with an ever-increasing number of Bluetooth™ enabled desktop computers, laptop computers, slate PCs, handheld devices, and keyboards, for example. The first and second keyboard units 102 and 104 may be coupled to provide input to the processor via a Bluetooth™ transmitter in which the processor is responsive to pressure exerted on the input keys by the user.

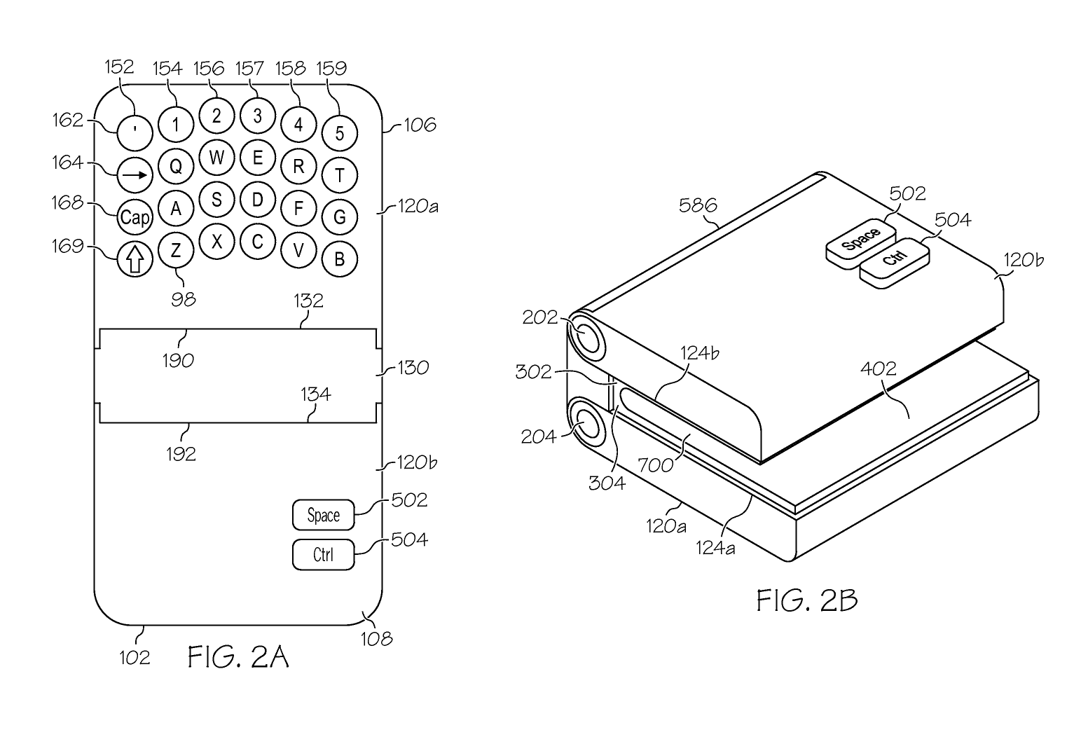

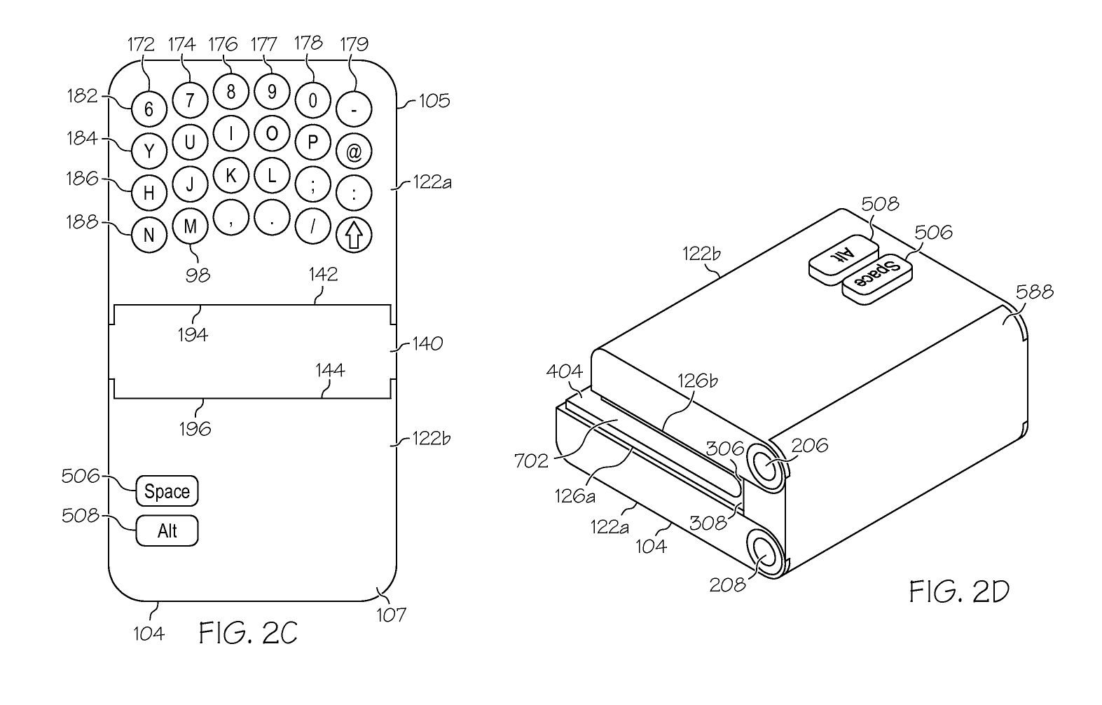

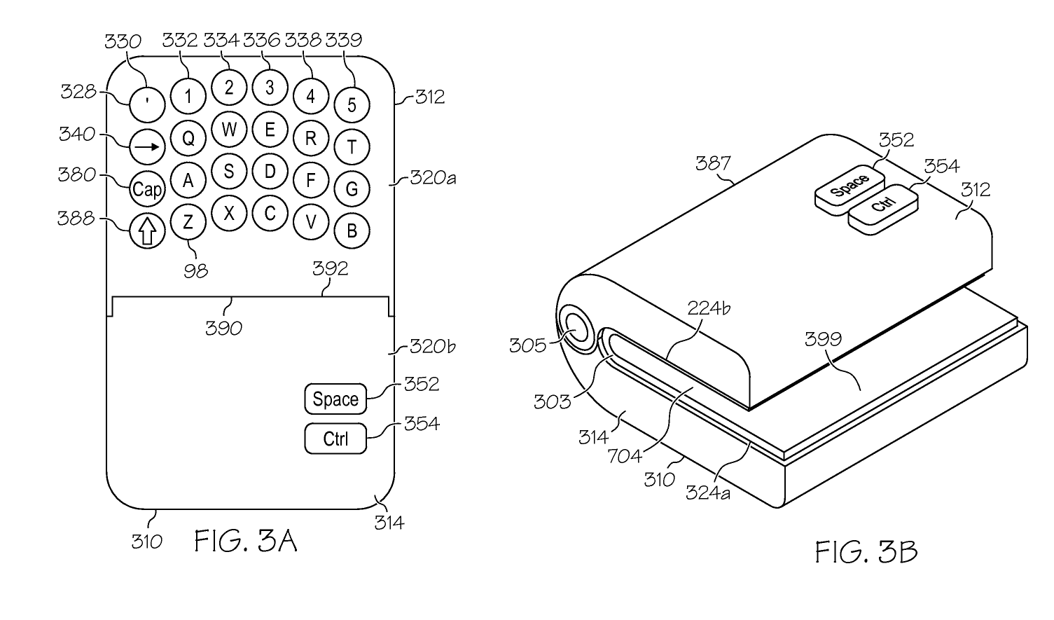

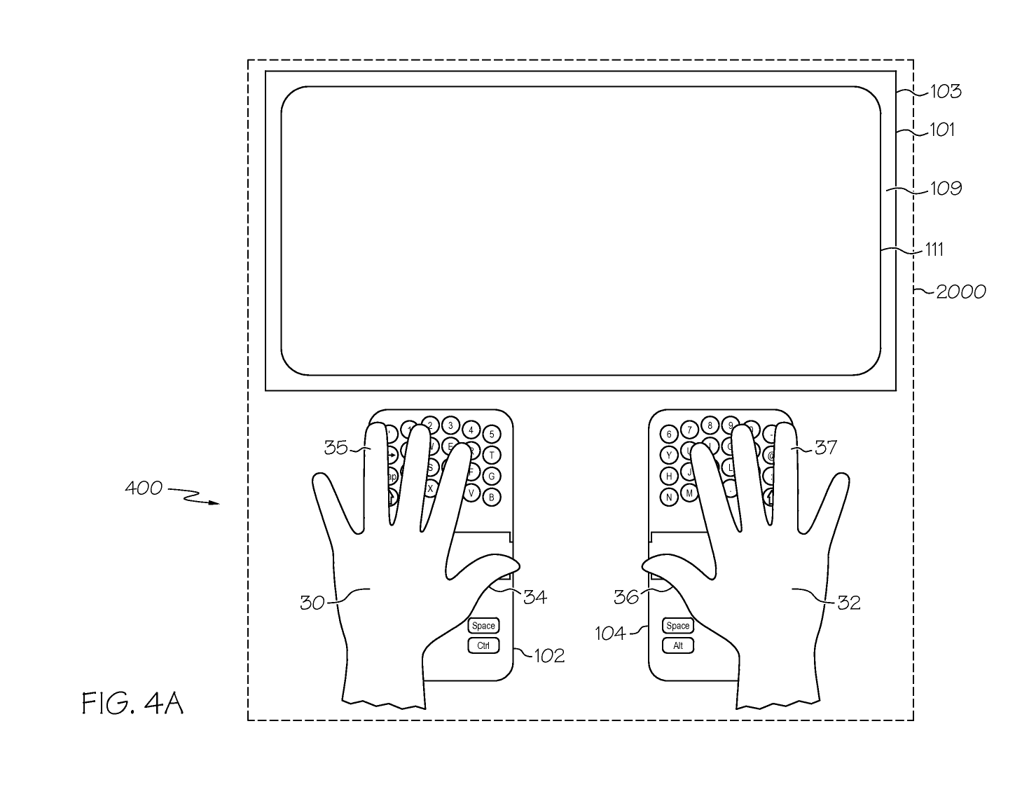

Referring to FIGS. 2A through 2D, generally, the first and second keyboard units 102 and 104 may include a plurality of keys 98. While the keys 98 of the illustrated keyboard units 102 and 104 are arranged in a grid pattern comprising a plurality of columns and a plurality of rows, the keys 98 may be arranged in various other patterns and layouts. Rows and/or columns may be straight, curved, or otherwise. While round and oval keys are shown, other shaped keys may be utilized. Each key 98 may be associated with at least one indicia representing an alphabetic character, a number, or a command (such as a space command, return command, or the like). The keys 98 having alphabetic characters may be arranged in a standard keyboard layout. The standard keyboard layout may be a OWERTY layout (as shown), a OZERTY layout, a QWERTZ layout, an AZERTY layout, a Dvorak layout, a Russian keyboard layout, a Chinese keyboard layout, a Japanese keyboard layout, or other layouts. These layouts are provided by way of example and other layouts are considered within the scope of the disclosure. The keyboard layout may be based on the geographical region in which the keyboard is intended for sale.

The keys 98 having alphabetic characters may also have numeric indicia. Such keys 98 may have the numerals arranged in a telephone keyboard layout, such as one according to the International Telecommunications Union (“ITU”) Standard E. 161, entitled “Arrangement of Digits, Letters, and Symbols on Telephones and Other Devices That Can Be Used for Gaining Access to a Telephone Network” (also known as ANSI TI.703-1995/1999 and ISO/IEC 9995-8:1994). A toggle key, such as a “Num Lock” key (not shown), may enable users to activate or deactivate the Num Lock function to use either the alphabetic characters or the associated numerals. In an exemplary embodiment, there may be keys 98 which bear only numerals, and those numerical keys may be grouped together separately from the keys bearing alphabetic characters. The numerals may, for example, be located near the top outer edge of the keyboard units 102 and 104 (as shown).

Referring to 2A and 2B, the first keyboard unit 102 may include an upper housing 106 connected to a lower housing 108 via a folding linkage assembly 130. The upper housing 106 of the first keyboard unit 102 may further include a bottom/inner surface 124a and an operational surface 120a which is on the opposite side of the bottom/inner surface 124a. The lower housing 108 of the first keyboard unit 102 may further include a bottom/inner surface 124b and an operational surface 120b which is on the opposite side of the bottom/inner surface 124b. In an exemplary embodiment, the first keyboard unit 102 may be designed for use with a user's left hand.

The upper housing 106 of the first keyboard unit 102 may include keys associated with “'” “1”, “2”, “3”, “4”, and “5” in a first row 162; keys associated with “tab”, “Q”, “W”, “E”, “R”, and “T” in a second row 164; keys associated with “caps lock”, “A”, “S”, “D”, “F”, and “G” in a third row 168; and keys associated with “shift”, “Z”, “X”, “C”, “V”, and “B” in a fourth row 169.

The upper housing 106 of the first keyboard unit 102 may additionally include keys associated with “'” “Tab”, “caps lock”, and “Shift” in a first column 152; and keys associated with “1”, “Q”, “A”, and “Z” in a second column 154. Keys in columns 152 and 154 may be positioned such that each of the keys may be operated by a pinky finger of a user's left hand.

The upper housing 106 may further include keys associated with “2”, “W”, “S”, and “X” in a third column 156; keys associated with “3”, “E”, “D”, and “C” in a fourth column 157; keys associated with “4”, “R”, “F” and “V” in a fifth column 158; and keys associated with “5”, “T”, “G”, and “B” in a sixth column 159. Keys in columns 156 and 157 may be positioned such that each of the keys may be operated by a ring finger and a middle finger, respectively. Keys in columns 158 and 159 may be positioned such that each of the keys may be operated by an index finger.

The upper housing 106 and lower housing 108 may include edges 190 and 192, respectively. The lower housing 108 may include keys associated with “space” 502 and “Ctrl” 504. In another exemplary embodiment, the lower housing 108 may further include functional keys, such as “F1”, “F2”, “F3”, for example. Toggle keys, such as “Ctrl” 504, for example, may be useful when a user intends to input different language characters other than English alphabets. For example, to enter a Japanese character, a user may press the “space” key 502, then press “Ctrl” 504, for example, to switch from English character input to Japanese character input.

The folding linkage assembly 130 in the first keyboard unit 102 may connect the upper housing 106 with the lower housing 108. A first end 134 of the folding linkage assembly 130 may be coupled to a first folding linkage receiving element 202. The first folding linkage receiving element 202 may be disposed transversely across the edge 192 of the lower housing 108. A second end 132 of the folding linkage assembly 130 may be coupled to a second folding linkage receiving element 204. The second folding linkage receiving element 204 may be disposed transversely across the edge 190 of the upper housing 106. The folding linkage assembly 130 may serve not only to support the upper housing 106, but also to provide a connection mechanism between the upper housing 106 and the lower housing 108. The folding linkage assembly 130 and the upper housing 106 may pivot on the first folding linkage receiving element 202 over substantially 90 degrees of angular movement with respect to the lower housing 108. The upper housing 106 may pivot on the second folding linkage receiving element 204 over substantially 90 degrees of angular movement with respect to the lower housing 108.

Still in FIG. 2B, the first keyboard unit 102 may further include a recess 586 for continuous contact with a first dorsal interosseous portion of the user's hands. The first keyboard unit 102 may further include a set of biasing elements 302 and 304. The biasing elements 302 and 304 may be attached to the first folding linkage receiving element 202 and the second receiving element 204, respectively, in order to support the upper housing 106 and the folding assembly 130 relative to the lower housing 108. The first keyboard unit 102 may further include an elongated member 402, which may be attached to the upper housing bottom 124a and the lower housing bottom 124b. The elongated member 402 may be made of a resilient, soft, and deformable material, such as rubber. The elongated member 402 may function to protect the surface of a slate PC when the first keyboard unit 102 is clamped onto the edge of the slate PC.

As shown in FIGS. 2C and 2D, a second keyboard unit 104 may have an upper housing 105 connected to a lower housing 107 via a folding linkage assembly 140. The second keyboard unit 104 may be designed for use with a user's right hand.

The upper housing 105 of the second keyboard unit 104 may include a bottom/inner surface 126a and an operational surface 122a which is on the opposite side of the bottom 126a. The lower housing 107 of the second keyboard unit 104 may further include a bottom/inner surface 126b and an operational surface 122b which is on the opposite side of the bottom 126b. The upper housings 105 and lower housing 107 may include edges 194 and 196, respectively.

The upper housing 105 of the second keyboard unit 104 may include keys associated with “6”, “7”, “8”, “9”, “0”, and “-” in a first row 182; keys associated with “Y”, “U”, “I”, “O”, “P”, and “@” in a second row 184; keys associated with “H”, “J”, “K”, “L”, “;”, and “:” in a third row 186; and keys associated with “N”, “M”, “,”, “.”, “/”, and “shift” in a fourth row 188.

The upper housing 105 of the second keyboard unit 104 may include keys associated with “6”, “Y”, “H”, and “N” in a first column 172; keys associated with “7”, “U”, “J”, and “M” in a second column 174; keys associated with “8”, “I”, “K”, and “,” in a third column 176; keys associated with “9”, “O”, “L”, and “.” in a fourth column 177; keys associated with “0”, “P”, “;”, and “/” in a fifth column 178; keys associated with “-”, “@”, “:”, and “Shift” in a sixth column 179. Keys in columns 176 and 177 may be positioned such that each of the keys may be operated by a middle finger or a ring finger of a right hand. Keys in columns 172 and 174 (or 178 and 179) may be positioned such that each of the keys may be operated by an index finger or a pinky finger.

The lower housing 107 may include keys associated with “space” 506 and “Alt” 508. In another exemplary embodiment, the lower housing 107 may further include functional keys, such as “F4”, “F5”, “F6”, for example. Toggle keys, such as “Alt” 508, for example, may be useful when a user intends to enter a Chinese character, a user may press the “space” key 506, then press “Alt” 508, for example, to switch from English character input to Chinese character input.

Similar to the first keyboard unit 102, the folding linkage assembly 140 of the second keyboard unit 104, connecting the upper housing 105 with the lower housing 107, may have a first end 142 which may be coupled to a first folding linkage receiving element 208. The first folding linkage receiving element 208 may be disposed transversely across the edge 194 of the upper housing 105. The folding linkage assembly 140 may have a second end 144 which may be coupled to a second folding linkage receiving element 206. The second folding linkage receiving element 206 may be disposed transversely across a bottom edge 196 of the lower housing 107. The folding linkage assembly 140 may serve not only to support the upper housing 105, but also to provide a connection mechanism between the upper housing 105 and the lower housing 107.

The folding linkage assembly 140 and the upper housing 105 may pivot on the second folding linkage receiving element 206 over substantially 90 degrees of angular movement with respect to the lower housing 107. The upper housing 105 may also pivot on the first folding linkage receiving element 208 over substantially 90 degrees of angular movement with respect to the lower housing 107.

Referring to FIG. 2D, the second keyboard unit 104 may further include a recess 588 for continuous contact with a first dorsal interosseous portion of the user's hands. The second keyboard unit 104 may further include a set of biasing elements 306 and 308. The biasing elements 306 and 308 may be attached to the second folding linkage receiving element 206 and the first folding linkage receiving element 208 respectively in order to support the upper housing 105 and the folding assembly 140 at various angular positions relative to the lower housing 107. The second keyboard unit 104 may further include an elongated member 404, attached to the bottom 126a and 126b. The elongated member 404 may be made of a resilient, soft, and deformable material, such as rubber. The elongated member 404 may function to protect the surface of a slate PC when the second keyboard unit 104 is attached onto an edge of the slate PC.

The first and second keyboard units 102 and 104 may utilize various switches, such as mechanical switches or dome-switches, for example. The dome-switch keyboard may comprise four layers, the keyboard, dome-switches, a flexible circuit board, and a keyboard supporting plate. Keys 98 on the keyboard units 102 and 104 may be made of plastic.

In operation, when the keyboard system 100 is in its open mode, as shown in FIGS. 2A and 2C, the upper housings 106 and 105, the folding linkage assemblies 130 and 140, and lower housings 108 and 107 may be aligned in a substantially level plane relative to each other, respectively. In moving from the open mode to the folded mode as shown in FIG. 2B and FIG. 2D, the upper housing 106 or 105 may pivot on the linkage receiving elements 202, 204 or 206, 208, thereby exposing the input keys 98. In the folded mode, cavities 700 or 702 may be formed when the upper housings 106 and 105 and the linkage assemblies 130 and 140 are folded toward the lower housings 108 and 107 respectively. One edge of a slate PC may be attached to the keyboard units 102 and 104 and may be sandwiched in the cavities 700 and 702 between the upper housings 106 and 105 and the lower housings 108 and 107.

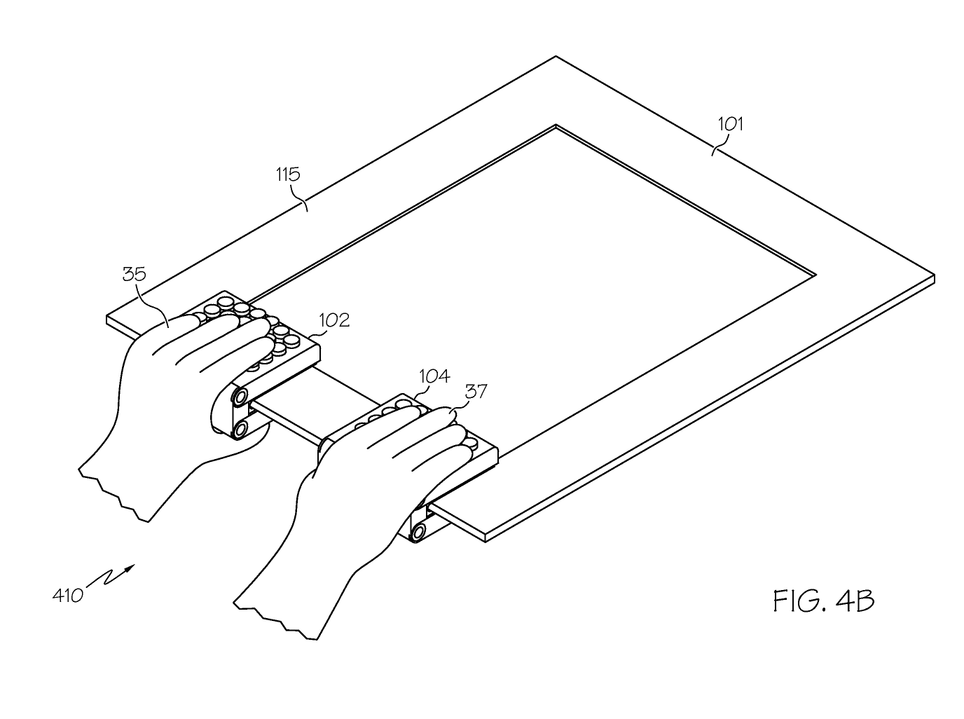

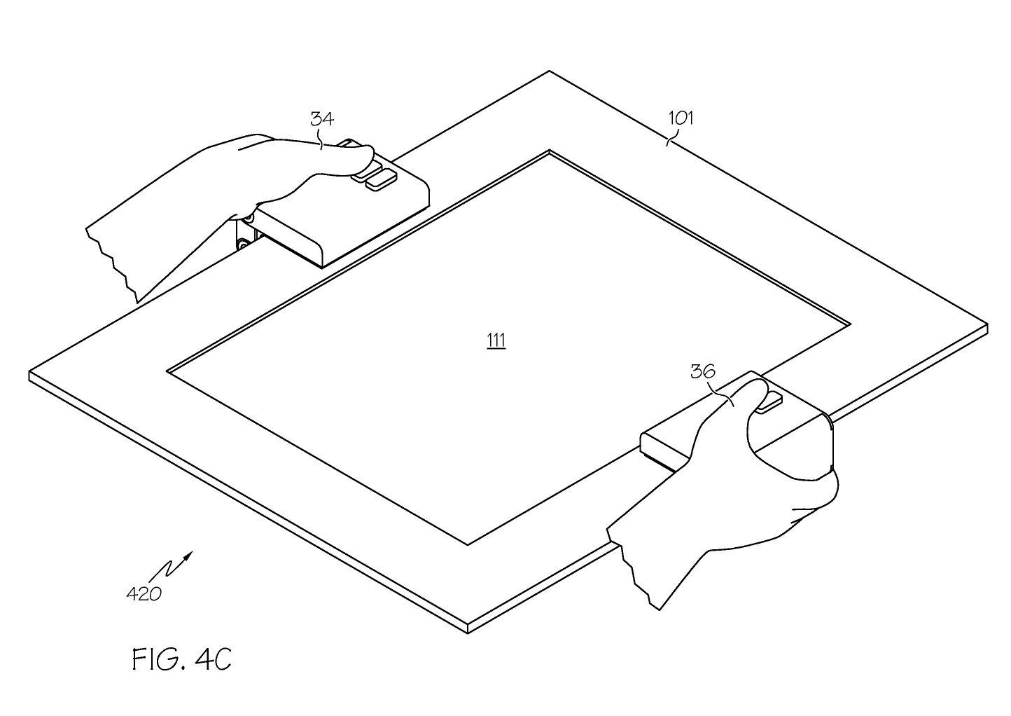

Referring to FIGS. 3A and 3B, in another exemplary embodiment, the upper housing 312 may be connected to the lower housing 314 by a folding linkage receiving element 305. The exemplary embodiment may be like a clamshell which may include an upper clamshell 312 and a lower clamshell 314 with a biasing element 303 connected to the linkage receiving element 305.

In a further exemplary embodiment of the present invention, the separate keyboard units may be made of one piece deformable materials, such as soft metal or plastic, for example. The one-piece keyboard units (not shown) may have neither the folding linkage structure nor the linkage receiving elements as described above. The one-piece keyboard unit may have its upper and lower portions separated by a predetermined angle. This angle may be resiliently deformed (by pulling apart the upper and lower portions) to a larger angle to permit attaching the one-piece keyboard unit to an edge of a slate PC.

In an alternative exemplary embodiment, separate keyboard units may be fabricated as part of a mitten or a glove so that hands may slip into the mitten or the glove and may be held by hands. Keys disposed in the glove or the mitten may have direct contact with fingers and thumbs. In addition, fingers may have enough space to move relative freely and type the keys in different columns and rows.

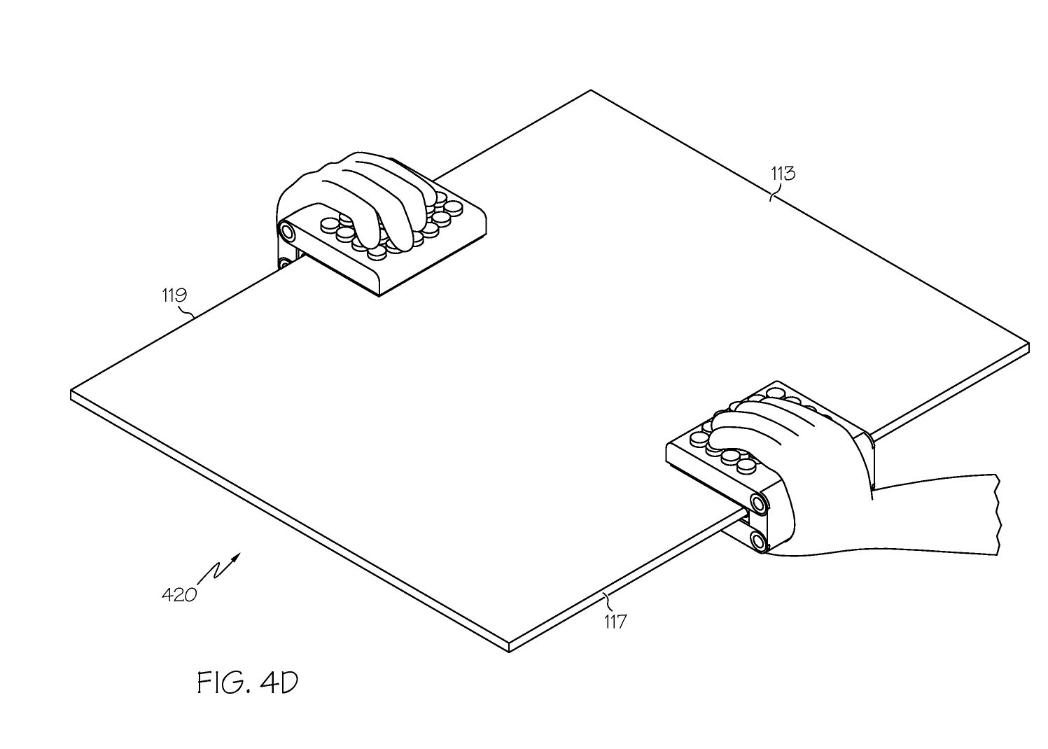

FIGS. 4A-4D show the steps for using the exemplary embodiments shown in FIGS. 2A through 2D. An exemplary embodiment of the keyboard units 102 and 104 may be unfolded and placed on a desk 2000, side by side, in front of a slate PC 101 as shown in step 400 shown in FIG. 4A.

Users may align their fingers 37 and thumb 36 of their right hand 32 with keys on the upper housing and the lower housing of the second keyboard unit 104. The user may align their fingers 35 and thumb 34 of their left hand 30 with keys on the upper housing and the lower housing of the first keyboard unit 102. Users may use the keyboard units 102 and 104 to enter data in the same way as a regular keyboard.

In step 410 as shown in FIG. 4B, the keyboard units 102 and 104 may be folded and clamped to a single edge 115 of the slate 101 with finger keys facing upward and thumb keys facing downward. The keyboard units 102 and 104 may be gripped by two hands 30 and 32 with four fingers positioned on the keyboard in front of the screen 111 while thumbs 34 and 36 may be positioned on the keyboard at a rear face 113 of the slate 101. In step 410, users may use the keyboard units 102 and 104 in the same way as a regular keyboard except that the thumbs 34, 36 may be positioned under the slate PC 101. Steps 410 and 420 provide users the opportunities to get familiar with the key positions on the keyboard units 102 and 104.

In step 420 as shown in FIGS. 4C and 4D, users may fold the keyboard units 102 and 104 and clamp the keyboard units 102 and 104 on opposite edges 117 and 119 of the slate 101 respectively with thumb keys facing upward and finger keys facing downward. The keyboard units 102 and 104 may be gripped by two hands 30 and 32 with four fingers positioned on the keyboard at the rear face 113 of the slate 101 while thumbs 34 and 36 may be positioned at front face 109 of the slate PC 101. After users get used to key locations on the upper housing and the lower housing of the keyboard in steps 400 and 410, they may feel comfortable in using keyboard units 102 and 104 to blind type in step 420 with fingers positioned under the slate 101.

It should be understood, of course, that the foregoing relate to exemplary embodiments of the invention and that modifications may be made without departing from the spirit and scope of the invention as set forth in the following claims.

We claim:

1. A keyboard system comprising:
a first keyboard unit and a second keyboard unit, the first and second keyboard units having a first housing and a second housing, respectively, wherein the first housing and the second housing are adapted to be attached and detached from an electronic device; and
a set of input keys disposed on at least one of the first and second housings.

2. The keyboard of claim 1, wherein the first housing is adapted to move pivotally on the second housing.

3. The keyboard of claim 1, further comprising an elongated member adapted to attach to the bottom of the first and second keyboard units.

4. The keyboard of claim 3, wherein the elongated member is formed of a resilient, soft, deformable material.

5. The keyboard of claim 4, wherein the resilient, soft, and deformable material is rubber.

6. The keyboard of claim 1, further comprising a folding linkage assembly having a first end coupled to a first folding linkage receiving element disposed transversely across a rear portion of the first housing and a second end coupled to a second folding linkage receiving element disposed transversely across a rear portion of the second housing.

7. The keyboard of claim 6 further comprising a biasing element attached to each of the folding linkage receiving element.

8. The keyboard of claim 2, wherein the first housing pivots over substantially 90 degrees of angular movement with respect to the second housing.

9. The keyboard of claim 6, wherein the folding linkage assembly is adapted to move pivotally on at least one of the first and second housings.

10. An electronic computing device comprising:
a housing having a front face and an opposing rear face;
a processor within the housing;
a screen attached to the housing at the front face in which the screen is coupled to be operable by the processor to display data to a user of the device; and
first and second foldable keyboard units comprising input keys, the first and second foldable keyboard units are adapted to be detachably affixed to an edge of the housing.

11. The electronic computing apparatus of claim 10, wherein the screen is a touch screen.

12. The electronic computing apparatus of claim 10, wherein at least a portion of the input keys on the first and second foldable keyboard units are positioned at the rear face of the housing for operation by the user's fingers.

13. The electronic computing apparatus of claim 10, wherein the first and second foldable keyboard units comprise at least one thumb key positioned at the front face of the housing for operation by the user's thumb.

14. The electronic computing apparatus of claim 13, wherein the thumb key comprises at least two thumb keys.

15. The electronic computing apparatus of claim 10, wherein the first and second foldable keyboard units are configured to be detached from the housing and attached thereto by the user.

16. A foldable keyboard comprising:
a lower housing; and
an upper housing operably coupled to the lower housing for movement between an open mode and a folded mode,
wherein, in the open mode, the foldable keyboard is detachable from a slate PC; and
wherein, in the folded mode, the foldable keyboard is adapted to affix to an edge of the slate PC in a position permitting blind data entry via keys in at least one of the lower housing and the upper housing.

17. The foldable keyboard of claim 16, further comprising a first set of keys disposed on an operational surface of the upper housing.

18. The foldable keyboard of claim 17, further comprising a second set of keys disposed on an operational surface of the lower housing.

19. The foldable keyboard of claim 17, wherein the first set of keys are operable by a user's fingers.

20. The method of claim 19, wherein the second set of keys are operable by a user's thumbs.
